(19) United States
(12) Patent Application Publication
(10) Pub. No.: US 2014/0071642 A1
(43) Pub. Date: Mar. 13, 2014

(54) LOW STRESS COMPONENT PACKAGE

(71) Applicant: Horst THEUSS, Wenzenbach (DE)

(72) Inventor: Horst THEUSS, Wenzenbach (DE)

(21) Appl. No.: 13/609,491

(22) Filed: Sep. 11, 2012

(51) Int. Cl. H05K 7/14

(52) U.S. Cl. 361/753

(57) ABSTRACT

Representative implementations of devices and techniques provide mechanical isolation to a sensor component mounted within a housing. The housing may have a cavity, and may be arranged such that the cavity faces a carrier. An aperture may be located in a surface of the housing to provide access to the sensor component.

### BACKGROUND

Many modern applications use sensor devices to collect data relating to the various applications. Pressure sensors, for example, may collect data regarding pressure conditions associated with different parts of a system (e.g., tire pressure, manifold pressure, etc.). The data collected by the sensor devices may be available for processing by a processor, for example.

In the case of a pressure sensor, it is important to mount the sensor so that it experiences little to no mechanical tension. For example, if the sensor is exposed to mechanical tension, the output of the sensor may be degraded or inaccurate (e.g., sensor drift, etc.). At the same time, it is also important to mount the sensor so that it is protected from damage by outside elements or forces. It can be problematic to mount the sensor in a manner to provide protection and to ensure that the sensor is free from mechanical stresses.

In some applications, the sensor may be encapsulated within a package, such as an integrated circuit (IC) package, or the like. However, in many of these applications, the sensor may be exposed to various mechanical stresses related to the IC package.

### BRIEF DESCRIPTION OF THE DRAWINGS

The detailed description is set forth with reference to the accompanying figures. In the figures, the left-most digit(s) of a reference number identifies the figure in which the reference number first appears. The use of the same reference numbers in different figures indicates similar or identical items.

For this discussion, the devices and systems illustrated in the figures are shown as having a multiplicity of components. Various implementations of devices and/or systems, as described herein, may include fewer components and remain within the scope of the disclosure. Alternately, other implementations of devices and/or systems may include additional components, or various combinations of the described components, and remain within the scope of the disclosure.

FIG. 1A is a cross-sectional profile view of an example pressure sensor, according to an implementation.

FIG. 1B is a cross-sectional profile view of the example sensor of FIG. 1A, encapsulated within an integrated circuit (IC) package. The package is shown in cross-section to reveal some detail.

FIG. 2A is a cross-sectional profile view of an example housing, which may be employed to house a sensor, for example.

FIG. 2B is a cross-sectional profile view of an example housing arrangement, arranged to house an electrical component such as the sensor of FIG. 1, according to an implementation.

FIG. 3A is a cross-sectional profile view of another example housing arrangement, arranged to house an electrical component such as the sensor of FIG. 1, according to an implementation.

FIG. 3B is a cross-sectional profile view of the example housing arrangement of FIG. 3A, surrounded by a shell, according to an implementation.

FIG. 4 is a cross-sectional profile view of a further example housing arrangement, arranged to house an electrical component such as the sensor of FIG. 1, according to a further implementation.

FIG. 5 is a flow diagram illustrating an example process for mechanically isolating an electrical component such as a sensor within a housing, according to an implementation.

### DETAILED DESCRIPTION

### Overview

Representative implementations of devices and techniques provide mechanical isolation to an electrical component, such as a sensor, mounted within a housing (e.g., package). The housing may have a cavity, and may be arranged such that the cavity faces a carrier (e.g., mounting component), when the housing is coupled to the carrier. An aperture may extend through a surface of the housing to provide access to the sensor component.

In one implementation, an elastic material is arranged to at least partially fill the cavity and surround the sensor component. The elastic material may provide additional mechanical isolation to the component within the housing.

In alternate implementations, multiple electrical components may be mounted within the housing, along with the sensor component. In one example, additional components or circuits may be coupled to the sensor component.

Various implementations and arrangements are discussed with reference to electrical and electronics components and varied carriers. While specific components (i.e., pressure sensors) are mentioned, this is not intended to be limiting, and is for ease of discussion and illustrative convenience. The techniques and devices discussed with reference to a sensor housing are applicable to any type or number of electrical components (e.g., sensors, transistors, diodes, etc.), circuits (e.g., integrated circuits, analog circuits, digital circuits, mixed circuits, etc.), groups of components, packaged components, structures, and the like, that may be mounted within a housing. For ease of discussion, the generic terms “sensor” and “electrical component” are used herein to describe any of the above.

Further, the techniques and devices discussed with reference to a housing or package are applicable to any type of carrier (e.g., board, chip, wafer, substrate, printed circuit board (PCB), package, container, can, module, etc.) that the housing may be mounted to. For ease of discussion, the generic term “carrier” is used herein.

Implementations are explained in more detail below using a plurality of examples. Although various implementations and examples are discussed here and below, further implementations and examples may be possible by combining the features and elements of individual implementations and examples.

### Example Sensor

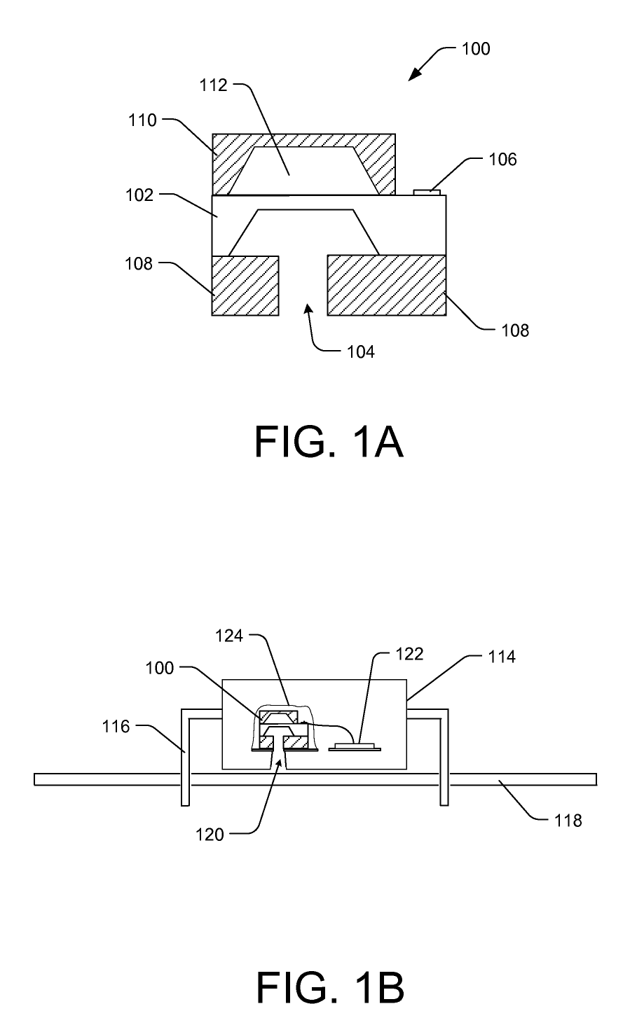

FIG. 1A is a cross-sectional profile view of an example pressure sensor (“sensor”) 100, according to an implementation. The sensor 100 represents an example electrical component whereby the techniques and devices discussed herein may be applied. For example, the sensor 100 represents any and all electrical components that may be mounted within a housing, where the housing provides mechanical isolation to the electrical component. The techniques, components, and devices described herein with respect to the sensor 100 are not limited to the illustration in FIG. 1, and may be applied to other designs, types, and constructions of sensors or other electrical components without departing from the scope of the disclosure. In some cases, alternative components may be used to implement the techniques described herein.

In an example implementation, as shown in FIG. 1A, the sensor 100 may be a pressure sensor having various elements. For example, the sensor 100 may include a pressure sensor diaphragm 102 and a signal inlet 104. In the case of a pressure sensor, the signal inlet 104 provides for an ambient pressure signal to enter the sensor 100, and to act upon the diaphragm 102. For example, the signal may deform or modify a portion of the shape of the diaphragm 102, particularly as the pressure changes or varies.

In an implementation, the diaphragm 102 is a micro-machined piezoelectric diaphragm. In the implementation, as the signal deforms or modifies a shape of the diaphragm 102, an electric signal is generated at the contact 106 of the diaphragm 102. For example, the electric signal may be generated due to a stress in the crystalline or lattice structure of the diaphragm 102. In various implementations, the electric signal may be slight, transitory, or the like, during pressure variations.

In an implementation, as shown in FIG. 1, the sensor 100 may include a support element 108, arranged to support the diaphragm 102 on one side of the diaphragm 102. The support element 108 also provides the signal inlet 104 to the diaphragm 102. Further, the sensor 100 may include another support element 110, arranged to support the diaphragm 102 on another side of the diaphragm 102. The other support element 110 may include a cavity 112 arranged to allow the diaphragm 102 to change shape during pressure variations.

FIG. 1B is a cross-sectional profile view of the example sensor 100 of FIG. 1A, encapsulated within an integrated circuit (IC) package 114. For example, the package 114 may be substantially solid after it is formed, fully surrounding the items within the package. The package 114 is shown in cross-section to reveal some detail of the encapsulated sensor 100 within the package 114.

In various implementations, the package 114 includes one or more electrical connections 116 arranged to couple the package 114 to other circuits and/or components. In some implementations, the connections 116 are also arranged to secure the package 114 to a carrier 118 (e.g., a back plane, printed circuit board, substrate, etc.).

In an implementation, the package 114 includes a channel 120 to provide access to the signal inlet 104 of the sensor 100. In many cases, the channel 120 faces the carrier 118. In those cases, access to the channel 120 and/or the signal inlet 104 may be problematic.

In some implementations, an additional circuit 122 (e.g., IC, component, or the like) may be encapsulated within the package 114 with the sensor 100. For example, the additional circuit 122 may be coupled to the sensor 100.

The sensor component 100 is shown insulated from the package 114 by an insulation layer 124, according to the example implementation of FIG. 1B. In an implementation, the insulation layer 124 may mechanically isolate the sensor 100 from the package 114. However, in many cases, the insulation layer 124 is substantially viscous, and does not fully insulate the sensor 100 from the package 114. For example, the encapsulation material of the package 114 may come into contact with the sensor 100 during packaging. When this occurs, the sensor diaphragm 102 may be clamped, for example, and the electric signal generated by the diaphragm 102 may be degraded (e.g., diminished, drifted, etc.).

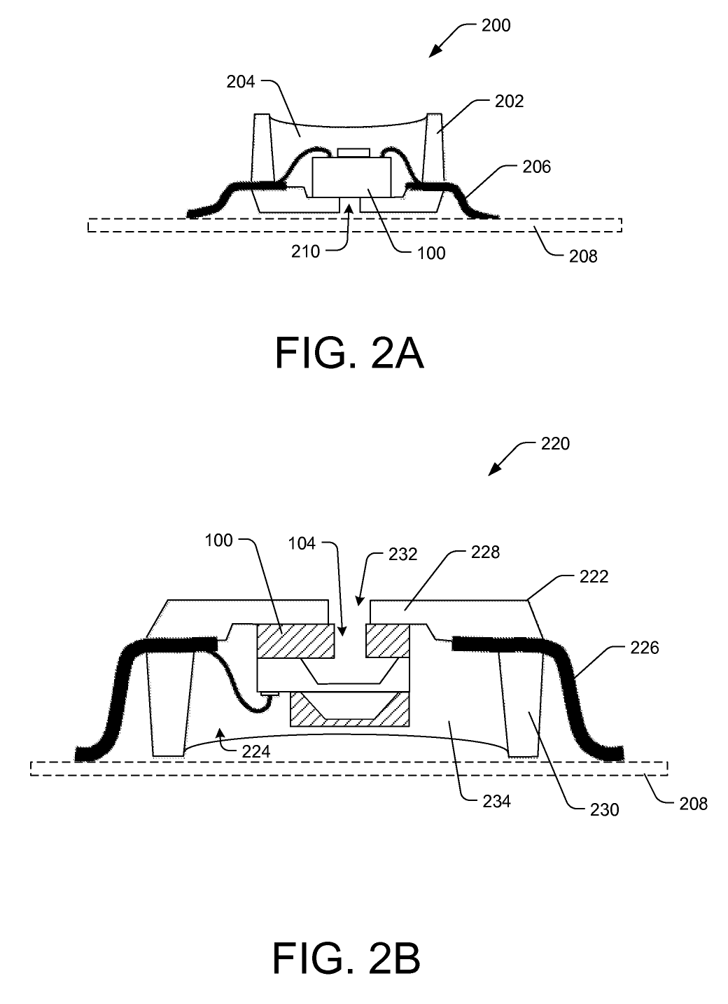

In an alternate implementation, as shown in FIG. 2A, a hollow package 200 may be used to house the sensor 100 (or other electrical component). In an example, the hollow package 200 may include a rigid housing 202, and may be filled with an elastic material 204 arranged to mechanically isolate the sensor 100 from the housing 202. Further, the package 200 may include one or more contacts 206 arranged to couple the sensor 100 to other electrical circuit components and/or couple the package 200 to a carrier 208 or other mounting component. The one or more contacts 206 are illustrated as extending or protruding through the housing 202. However, in another embodiment, the one or more contacts 206 do not extend through the housing 202. For example, the one or more contacts 206 may extend partially through the housing 202 or to a periphery of the housing 202, such as on sides of the housing 202 or on the bottom of the housing 202.

As shown in FIG. 2A, the package 200 may include a channel 210 to provide access to the sensor 100. However, as shown in the illustration, the channel 210 may be located on the same side of the package as the contacts 206. Consequently, the channel 210 may be difficult to interface with or to access, since it is in close proximity to the carrier 208 and faces the carrier 208.

### Example Housing Arrangement

FIG. 2B is a cross-sectional profile view of an example housing arrangement 220, including a housing 222 arranged to house an electrical component such as the sensor 100 of FIG. 1, according to an implementation. The housing arrangement 220 may be comprised of multiple elements, according to various implementations. In alternate implementations, the housing arrangement 220 may have fewer elements than illustrated in the example of FIG. 2B, or it may have more or alternative elements than those shown in FIG. 2B.

In one implementation, the housing 222 is a rigid housing, offering protection from outside elements and forces to the sensor 100 mounted within the housing 222. In some implementations, the housing 222 is arranged to enclose multiple electrical components (e.g., multiple devices, circuits, etc.). In an implementation, as shown in FIG. 2B, the housing 222 is substantially bowl-shaped, with an interior cavity 224. In various implementations, the housing 222 is oriented as an inverted bowl when coupled to a carrier 208.

In various implementations, the housing 222 is arranged to be coupled to a carrier 208. For example, in one implementation, the housing 222 includes one or more contacts 226 protruding from the housing 222 and arranged to couple the housing 222 to the carrier 208. In various implementations, the housing 222 is arranged to be coupled to the carrier 208 such that the cavity 224 faces the carrier. In this arrangement, the housing 222 provides protection to the sensor 100, while having a hollow interior. In an implementation, the contacts 226 are electrically coupled to the sensor 100. The one or more contacts 226 are illustrated as extending or protruding through the housing 222. However, in another embodiment, the one or more contacts 226 do not extend through the housing 222. For example, the one or more contacts 226 may extend partially through the housing 222 or to a periphery of the housing 222, such as on sides of the housing 222 or on the bottom of the housing 222.

In an implementation, the contacts 226 are surface mount technology (SMT) compatible. In other words, the contacts 226 are designed to couple the housing 222 to a carrier 208 using surface mount techniques (as compared to through-hole techniques, or the like). In other implementations, the contacts 226 are designed to couple the housing 222 to a carrier 208 using through-hole technology, or other mounting techniques and/or processes.

In one implementation, as shown in FIG. 2B, the housing 222 comprises a pre-molded casing having the one or more electrical contacts 226 molded into the casing and extending from the casing to couple the casing to the carrier 208. In various implementations, the casing may be a single molded element, or may be comprised of multiple molded elements coupled together, for example. In an implementation, the sensor 100 may be wire-bonded (or other method) to the electrical contacts 226.

In an implementation, the housing 222 is comprised of a substantially planar mounting surface 228 and one or more side surfaces 230 coupled to the mounting surface 228. In an implementation, the side surface(s) 230 extend away from the mounting surface 228, towards the carrier 208 for example, forming the interior cavity 224 of the housing 222. In various implementations, the side surface(s) 230 extend substantially normal (e.g., perpendicular) to the mounting surface 228, or may extend away at some other angle from the mounting surface 228.

In an implementation, the mounting surface 228 is arranged to couple the sensor 100 to an interior face of the mounting surface 228. For example, the sensor 100 may be mounted within the cavity 224 of the housing 222. In an implementation, as shown in FIG. 2B, the sensor 100 is mounted “upside-down” to the mounting surface 228 within the cavity 224. In other words, the sensor 100 is mounted to the mounting surface 228 so that the signal inlet 104 of the sensor 100 faces toward the mounting surface 228 and faces away from the carrier 208.

In one implementation, the housing 222 includes an aperture 232 extending through the mounting surface 228 and arranged to align with one or more portions of the sensor 100. For example, in an implementation, as shown in FIG. 2B, the signal inlet 104 of the sensor 100 is aligned with the aperture 232, providing access to the signal inlet 104. In this arrangement, the aperture 232 faces away from the carrier 208. Access to the aperture 232 and the signal inlet 104 of the sensor 100 may be improved with the aperture 232 and the signal inlet 104 facing away from the carrier 208.

In alternate implementations, the aperture 232 may be located at or near a center of the mounting surface 228, or at various other locations on the surface 228 (e.g., off-center, near an edge, etc.). In another implementation, the aperture 232 may be located on or near one of the side surfaces 230. In the alternate implementations, the aperture 232 may be aligned or channeled to the signal inlet 104, to provide access to the signal inlet 104.

In an implementation, as shown in FIG. 2B, the housing arrangement 220 includes an elastic material 234 arranged to at least partially fill the cavity 224 and to surround the sensor 100. In an implementation, the elastic material 234 provides mechanical isolation to the sensor 100 from the housing 222. For example, the elastic material 234 may completely surround the sensor 100. In a further implementation, the elastic material 234 fills the cavity 224, surrounding the sensor 100 and any other components within the cavity 224.

In one implementation, the housing arrangement 220 includes a rigid layer (not shown) arranged to cover the elastic material 234 and form a protective barrier. For example, the rigid layer may cover the elastic material 234, and/or seal the cavity 224 of the housing 222. In various implementations, the rigid layer may be applied to the housing arrangement 220 after the elastic material 234 is disposed within the cavity 224. In one implementation, the rigid layer is applied like a cap or lid to the housing 222, sealing the open end of the cavity 224, without fully filling the cavity 224 with elastic material 234. For example, the cavity 224 may be substantially filled with air, another gas, vacuum, or the like.

### Example Implementations

In various implementations, a housing arrangement 220 may be employed with other devices and/or components to provide mechanical isolation to the sensor 100. In various implementations, the housing arrangement 220, including the sensor 100, the housing 222, and the contact(s) 226 may be employed as a module or system. For example, in an implementation, the module may include a housing 222 arranged to be coupled to a carrier 208, where the housing includes a substantially planar mounting surface 228 having an aperture 232 extending through the mounting surface 228 and one or more side surfaces 230 coupled to the mounting surface 228 and extending towards the carrier 208, forming an interior cavity 224 of the housing 222. One or more contacts 226 extend from the housing 222 and are arranged to couple the housing 222 to the carrier 208. An electrical component such as the sensor 100 is coupled to an interior face of the mounting surface 228, within the cavity 224 of the housing 222. A portion of the sensor 100 is arranged to align with the aperture 232. In alternate implementations, the housing arrangement 220 may include fewer, additional, or alternative elements and remain within the scope of the disclosure.

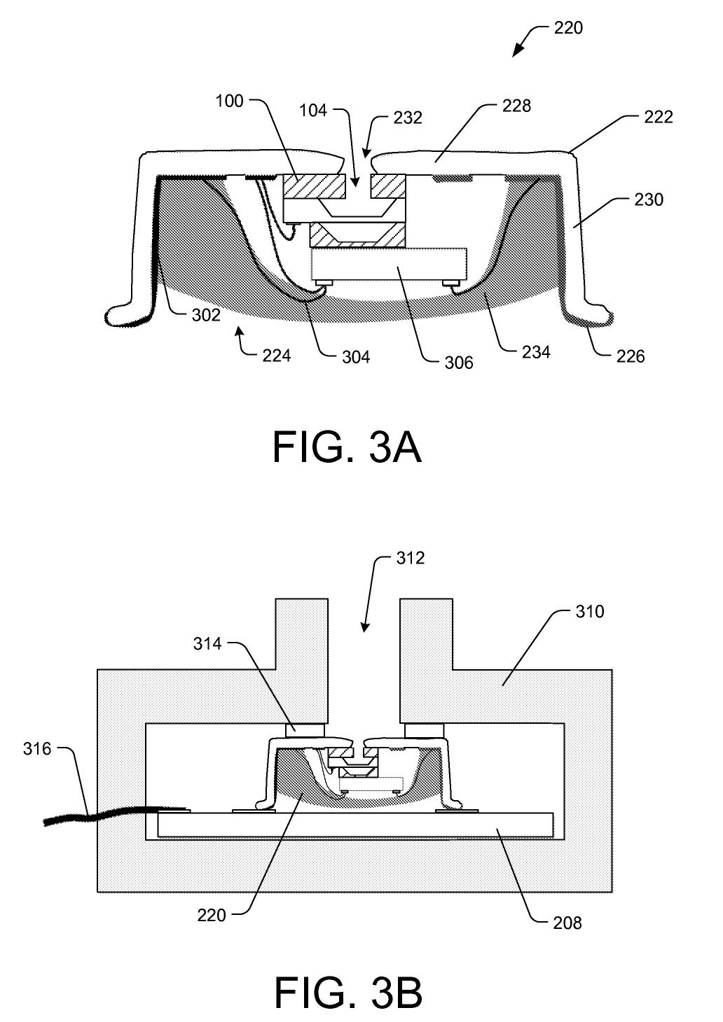

FIG. 3A is a cross-sectional profile view of an example housing arrangement 220, arranged to house an electrical component such as the sensor 100, according to another implementation. The housing arrangement 220 comprises a molded interconnect device (MID) housing 222 with selective conductor tracks 302 located at the interior of the housing 222. For example, conductive metallic tracks 302 may be embedded within the mounting surface 228 and/or the side surface(s) 230. In the example, the conductive metallic tracks 302 have an exposed portion for making an electrical connection with the sensor and/or other devices within the cavity 224 of the housing 222. Alternately, the conductive metallic tracks 302 may be disposed onto the interior surface of the housing 222, and the like.

When multiple electrical components are housed within the cavity 224, one or more wires 304 may be used to connect the various components within the cavity 224 to the conductor tracks 302. Alternately, the wire(s) 304 may be used to solely connect the sensor 100 to one or more of the conductor tracks 302.

In an implementation, as shown in FIG. 3A, a component 306 such as a logic circuit, for example, may be located adjacent to or stacked with the sensor 100 within the cavity 224. Different mounting configurations for additional component(s) 306 may be possible with different implementations.

FIG. 3B is a cross-sectional profile view of the example housing arrangement 220 (or module) of FIG. 3A, surrounded by a rigid shell 310, according to an implementation. As shown in FIG. 3B, the shell 310 may include a channel 312 arranged to be aligned with the aperture 232 of the housing 222 and/or the signal inlet 104 of the sensor 100. In various implementations, the shell may have any shape and size appropriate for the application. The shell may be mounted to a location within the application system (e.g., vehicle, machine, process device, etc.) where the sensor is needed to collect sensory information. In an alternate implementation, the housing arrangement 220 may be mounted or located within the application system without a shell 310.

In an implementation, a seal 314 is disposed within the shell 310 and arranged to seal an outer face of the housing 222 to an inner face of the shell 310. In various implementations, the seal 314 is an o-ring, or other seal having a shape arranged to seal the shell 310 to the housing 222. For example, in the case of a pressure sensor application, the shell 310 can provide protection for the sensor 100 and the module/housing arrangement 220 against elements and outside forces while allowing access to the signal inlet 104 for ambient pressure. Further, the arrangement allows for the sensor 100 to be mechanically isolated, preserving the performance of the sensor 100.

In one implementation, the housing 222 is mounted to a printed circuit board (PCB) or other carrier 208 within the shell 310. For example, the housing 222 may be coupled to the PCB via one or more of the contacts 226, or the like. In an implementation, a conductor 316 may be coupled to the PCB and passed through an opening in the shell 310 for connection to a processor, and the like. In various implementations, other devices, circuits, and the like, may also be mounted to the PCB. For example, the sensory data may be pre-processed or conditioned by a circuit located on the PCB, prior to sending the result out on the conductor 316.

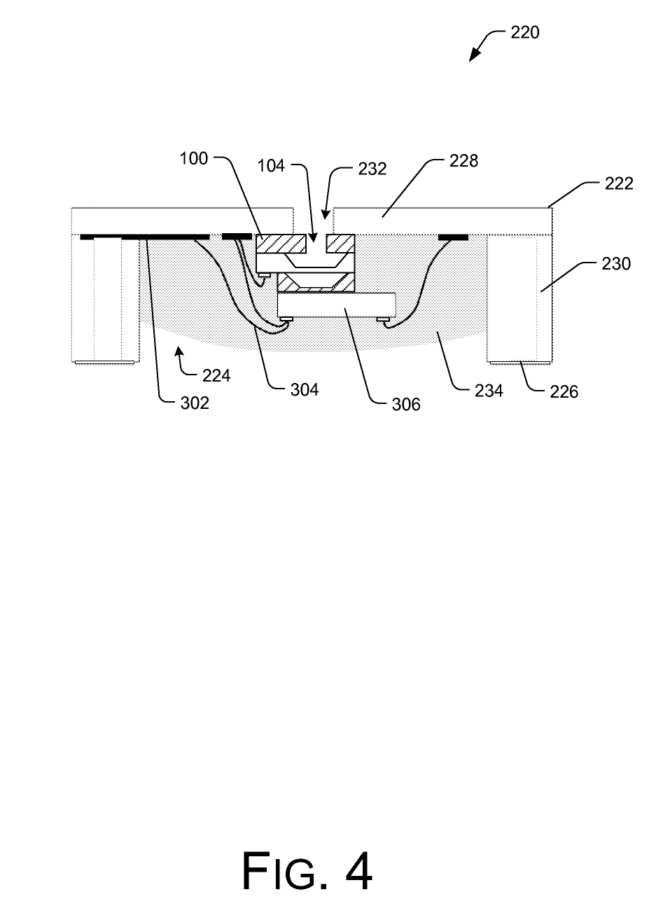

FIG. 4 is a cross-sectional profile view of a further example housing arrangement 220, arranged to house an electrical component such as the sensor 100 of FIG. 1, according to a further implementation. The housing arrangement 220 of FIG. 4 is an example arrangement 220 having a housing 222 comprised of a PCB, or similar element. For example, the housing 222 may be comprised of an organic PCB structure or a ceramic PCB structure, or the like.

In an implementation, as shown in FIG. 4, the sensor 100 is mounted to an interior face of the mounting surface 228. As shown in FIG. 4, the PCB-based housing includes an aperture 232 aligned with the signal inlet 104 of the sensor 100. Further, the cavity 224 is at least partially filled with an elastic material 234 that surrounds the sensor 100, as well as potentially surrounding additional components 306 within the cavity 224. For example, the additional components 306 may be partially surrounded or not surrounded in some implementations.

In various implementations, wires 304 may connect the sensor 100 and/or the additional components 306 to conductor traces 302 on interior faces of the mounting surface 228 and/or one or more side surfaces 230. Contacts 226 provide electrical and/or mechanical coupling of the housing 222 to a carrier 208, or the like. In various examples, the contacts are surface mount contacts, through-hole contacts, and so forth.

In alternate implementations, various other combinations and systems including the housing arrangement 220 are also within the scope of the disclosure. The variations may have fewer elements than illustrated in the examples shown in FIG. 2B through FIG. 4, or they may have more or alternative elements than those shown.

### Representative Process

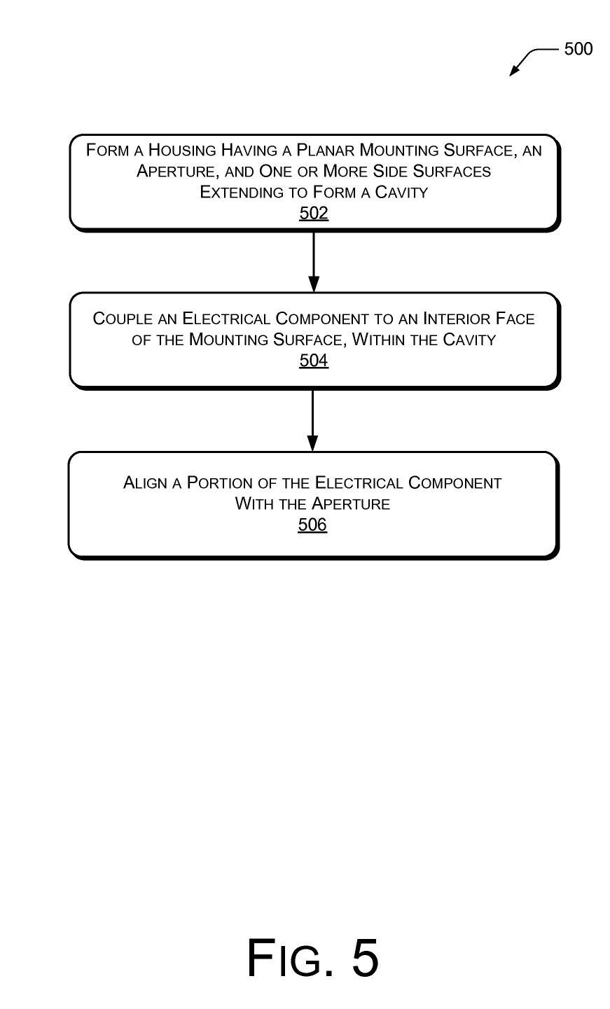

FIG. 5 illustrates a representative process 500 for mechanically isolating a component (such as sensor 100, for example) within a housing (such as housing 222, for example), according to various implementations. In some implementations, the housing may have a cavity (such as cavity 224, for example) where the component is mounted. The process 500 is described with reference to FIGS. 1-4.

The order in which the process is described is not intended to be construed as a limitation, and any number of the described process blocks can be combined in any order to implement the process, or alternate processes. Additionally, individual blocks may be deleted from the process without departing from the spirit and scope of the subject matter described herein. Furthermore, the process can be implemented in any suitable materials, or combinations thereof, without departing from the scope of the subject matter described herein.

At block 502, the process includes forming a housing (such as housing 222, for example). In an implementation, the housing includes: a substantially planar mounting surface (such as mounting surface 228, for example), an aperture (such as aperture 232, for example) extending through the mounting surface, and one or more side surfaces (such as such as side surface(s) 230, for example) coupled to the mounting surface. In an implementation, the side surface(s) extend to form an interior cavity (such as cavity 224, for example) of the housing. In an implementation, the housing is substantially bowl-shaped.

At block 504, the process includes coupling an electrical component (such as sensor 100, for example) to an interior face of the mounting surface, within the cavity. In an implementation, the electrical component is mounted in an upside-down orientation within the cavity. In alternate implementations, the electrical component is mounted in other orientations (e.g., sideways, diagonally, right-side up, etc.), and aligned to the aperture.

In an implementation, the process includes at least partially filling the cavity with an elastic material and surrounding the electrical component with the elastic material. For example, the elastic material can provide mechanical isolation (i.e., spacing from features and elements, mechanical shock isolation, etc.) for the electrical component. The elastic material can ensure that the electrical component is exposed to little or no mechanical tension. In one implementation, the process includes disposing a rigid layer over the elastic material (i.e., a cap, lid, covering layer, etc.).

At block 506, the process includes aligning a portion of the electrical component with the aperture. For example, a signal inlet of the electrical component may be aligned to the aperture, to provide access to the signal inlet. In an example implementation, the electrical component comprises a pressure sensor, and the aperture provides access for ambient pressure to be received at the signal inlet of the sensor.

In an implementation, the process includes coupling the housing to a carrier via contacts (such as contacts 226, for example), which in one implementation, that extend from the housing. For example, the housing may have one or more contacts extending from the housing, which may be used to couple the housing to a carrier (e.g., a PCB or the like). In another implementation, the process includes coupling the housing to a carrier via contacts (such as contacts 226, for example), which in one implementation, do not extend from the housing. Additionally, the contacts may be used to electrically couple the electrical component to a circuit or system outside the housing (on the PCB, for example).

In an implementation, the process includes coupling the housing to the carrier such that the cavity of the housing faces the carrier and the aperture faces away from the carrier. For example, this arrangement may be used to provide access to the signal inlet of the sensor (i.e., electrical component) while protecting the electrical component within the cavity of the housing.

In various implementations, the process includes mounting one or more other electrical components within the cavity of the housing and coupling one or more of the other electrical components to the electrical component. In an implementation, additional devices, circuits, and the like, may be housed within the cavity of the housing.

In one implementation, the process includes enclosing the housing within a rigid shell (such as shell 310, for example). Further, the shell may include a channel for access to the aperture of the housing, and the channel of the shell may be sealed to the aperture of the housing. For example, an o-ring or other type of seal may be used to seal the shell to the housing (as shown in FIG. 3B, for example).

In alternate implementations, other techniques may be included in the process 500 in various combinations, and remain within the scope of the disclosure.

### Conclusion

Although the implementations of the disclosure have been described in language specific to structural features and/or methodological acts, it is to be understood that the implementations are not necessarily limited to the specific features or acts described. Rather, the specific features and acts are disclosed as representative forms of implementing example devices and techniques.

What is claimed is:

1. A device, comprising:
a rigid housing for an electrical component, the housing arranged to be coupled to a carrier, the housing including:
a substantially planar mounting surface arranged to couple the electrical component to an interior face of the mounting surface;
an aperture extending through the mounting surface and arranged to align with a portion of the electrical component; and
one or more side surfaces coupled to the mounting surface and extending towards the carrier, forming an interior cavity of the housing; and
one or more contacts arranged to couple the housing to the carrier.

2. The device of claim 1, further comprising an elastic material arranged to at least partially fill the cavity and to surround the electrical component.

3. The device of claim 1, further comprising a rigid layer arranged to cover the elastic material and form a protective barrier.

4. The device of claim 1, wherein the electrical component comprises a sensor and a signal inlet of the sensor is aligned with the aperture.

5. The device of claim 4, wherein the sensor is mounted inside the cavity of the housing and the signal inlet of the sensor is oriented to face away from the carrier.

6. The device of claim 1, wherein one or more of the contacts are electrically coupled to the electrical component.

7. The device of claim 1, the housing further arranged to enclose multiple electrical components.

8. The device of claim 1, wherein the one or more contacts are surface mount technology (SMT) compatible.

9. The device of claim 1, wherein the housing is substantially bowl-shaped, with the cavity of the housing facing the carrier.

10. The device of claim 1, wherein the housing comprises a molded interconnect device (MID) housing with selective conductor tracks located at the interior of the housing.

11. The device of claim 1, wherein the housing comprises an organic printed circuit board (PCB) structure or a ceramic PCB structure.

12. The device of claim 1, wherein the housing comprises a pre-molded casing having one or more electrical contacts molded into the casing and extending from the casing to couple the casing to the carrier.

13. A module, comprising:
a housing arranged to be coupled to a carrier, the housing including:
a substantially planar mounting surface having an aperture extending through the mounting surface; and
one or more side surfaces coupled to the mounting surface and extending towards the carrier, forming an interior cavity of the housing;
one or more contacts arranged to couple the housing to the carrier; and
an electrical component coupled to an interior face of the mounting surface, within the cavity of the housing, a portion of the electrical component arranged to align with the aperture.

14. The module of claim 13, further comprising one or more other electrical components mounted within the cavity of the housing.

15. The module of claim 13, further comprising a rigid shell surrounding the housing, the shell including a channel aligned with the aperture.

16. The module of claim 15, further comprising a seal disposed within the shell and arranged to seal an outer face of the housing to an inner face of the shell.

17. The module of claim 15, further comprising the carrier, and wherein the carrier comprises a printed circuit board (PCB) mounted within the shell, the housing mounted to the PCB via the one or more contacts.

18. The module of claim 15, wherein the electrical component comprises a pressure sensor, and the channel and the aperture are aligned with a signal inlet on the pressure sensor.

19. A method, comprising:
forming a housing having:
a substantially planar mounting surface;
an aperture extending through the mounting surface; and
one or more side surfaces coupled to the mounting surface and extending to form an interior cavity of the housing;
coupling an electrical component to an interior face of the mounting surface, within the cavity; and
aligning a portion of the electrical component with the aperture.

20. The method of claim 19, further comprising at least partially filling the cavity with an elastic material and surrounding the electrical component with the elastic material.

21. The method of claim 19, further comprising coupling the housing to a carrier via contacts.

22. The method of claim 21, further comprising coupling the housing to the carrier such that the cavity of the housing faces the carrier and the aperture faces away from the carrier.

23. The method of claim 19, further comprising mounting one or more other electrical components within the cavity of the housing and coupling one or more of the other electrical components to the electrical component.

24. The method of claim 19, further comprising enclosing the housing within a rigid shell and sealing a channel of the shell to the aperture of the housing.

25. A module, comprising:
a hollow housing arranged to be surface-mounted to a printed circuit board (PCB), the housing including:
a substantially planar mounting surface having an aperture extending through the mounting surface; and
one or more side surfaces coupled to the mounting surface and extending towards the PCB, forming an interior cavity of the housing;
one or more contacts arranged to couple the housing to the PCB such that the cavity faces the PCB and the aperture faces away from the PCB;
a sensor component coupled to an interior face of the mounting surface, within the cavity of the housing, a signal inlet of the sensor component aligned with the aperture; and
an elastic material arranged to at least partially fill the cavity and to surround the sensor component.
